(19) United States
(12) Patent Application Publication
(10) Pub. No.: US 2016/0251555 A1
(43) Pub. Date: Sep. 1, 2016

(54) SILICONE ADHESIVE

(71) Applicant: SHIN-ETSU CHEMICAL CO., LTD., Tokyo (JP)

(72) Inventors: Mitsuhiro IWATA, Takasaki (JP); Eiichi TABEI, Annaka (JP)

(73) Assignee: SHIN-ETSU CHEMICAL CO., LTD., Tokyo (JP)

(21) Appl. No.: 15/031,621

(22) PCT Filed: Oct. 24, 2014
(86) PCT No.: PCT/JP2014/005400

§ 371 Date: Apr. 22, 2016

(30) Foreign Application Priority Data
Nov. 14, 2013 (JP) 2013-235759

(51) Int. Cl. C09J 183/04; H01L 33/62; H01L 23/00; C09J 11/04; C09K 5/14

(52) U.S. Cl. CPC C09J 183/04; C09J 11/04; C09K 5/14; H01L 24/83; H01L 33/62; H01L 2224/83862; H01L 2924/12041; H01L 2924/0715

(57) ABSTRACT

A silicone adhesive used for bonding semiconductor device, containing (A) addition reaction-curable silicone resin composition having viscosity at 25° C. of 100 Pa·s or less, (B) thermal conductive filler having average particle size of 0.1 μm or more and less than 1 μm, and (C) solvent having boiling point of 250° C. or higher and lower than 350° C., wherein component (B) is contained in an amount of 100 to 500 parts by mass based on 100 parts by mass of component (A), component (C) is contained in an amount of 5 to 20 parts by mass based on 100 parts by mass of component (A), and silicone adhesive uncured has viscosity at 25° C. of 5 to 100 Pa·s. Thus, silicone adhesive has good workability in transferring method to substrate, and is capable of providing cured product that can effectively dissipate heat generated from chip and exhibits high adhesiveness and durability.

### TECHNICAL FIELD

The present invention relates to a silicone adhesive used for bonding a semiconductor device.

### BACKGROUND ART

Conventionally, an epoxy resin has been used for a die bonding material (adhesive) for fixing a LED light-emitting device (chip). However, long-term use may cause the die bonding material fixing a blue or white LED light-emitting device to yellow over time and absorb light in a similar manner to an epoxy encapsulant, which causes the reduction in luminance (Patent Document 1).

Recently, demands on durability of a light-emitting apparatus using LED as a module have increased, and encapsulants for LED are shifting to a silicone type. Along with this, greater durability is also being demanded of die bonding materials as well as encapsulants.

In addition, since luminous efficiency of LED tends to decrease as a light-emitting device heats, improvement in heat dissipation property of die bonding materials is also required.

A method widely used for bonding a LED light-emitting device to a substrate with a die bonding material is a transferring method which includes applying a die bonding material on a perforated plate to form a thin film and transferring the thin film by stamping to a substrate on which a LED light-emitting device will be mounted. Therefore, in addition to the above properties, good workability for bonding by the transferring method is also demanded of die bonding materials.

### CITATION LIST

### Patent Literature

Patent Document 1: Japanese Unexamined Patent publication (Kokai) No. 2006-342200

### SUMMARY OF INVENTION

### Technical Problem

The present invention was accomplished in view of the above circumstances. It is an object of the present invention to provide a silicone adhesive that has good workability in the transferring method to a substrate, and is capable of providing a cured product that can effectively dissipate heat generated from a chip and exhibits high adhesiveness and excellent durability.

### Solution To Problem

To achieve this object, the present invention provides a silicone adhesive used for bonding a semiconductor device, comprising:

(A) an addition reaction-curable silicone resin composition having a viscosity at 25° C. of 100 Pa·s or less;

(B) a thermal conductive filler having an average particle size of 0.1 μm or more and less than 1 μm; and

(C) a solvent having a boiling point of 250° C. or higher and lower than 350° C., wherein

the component (B) is contained in an amount of 100 to 500 parts by mass based on 100 parts by mass of the component (A), the component (C) is contained in an amount of 5 to 20 parts by mass based on 100 parts by mass of the component (A), and the silicone adhesive uncured has a viscosity at 25° C. of 5 to 100 Pa·s.

Such a silicone adhesive has good workability in the transferring method to a substrate and is capable of providing a cured product that can effectively dissipate heat generated from a chip and exhibits high adhesiveness and excellent durability.

A cured product obtained by heating the component (A) at 150° C. for 3 hours preferably exhibits a type D hardness in accordance with JIS K 6253 of 30 degrees or more.

Such component (A) stabilizes the connectability also in a wire bonding step after a LED device is bonded.

The component (A) preferably comprises:

(a) an organopolysiloxane having 2 or more silicon-bonded alkenyl groups per molecule and having a viscosity at 25° C. of 1,000 mPa·s or less;

(b) an organopolysiloxane having 1 or more silicon-bonded alkenyl groups per molecule in a solid state or a liquid state having a viscosity at 25° C. of 1,000 Pa·s or more, shown by the following average composition formula (1), the component (b) being contained in an amount of 60 to 90 parts by mass based on 100 parts by mass of a total of the component (a) and the component (b),

(R¹R²₂SiO_{1/2})ₘ(R¹R²SiO_{2/2})ₙ(R²₂SiO_{2/2})ₚ(R¹SiO_{3/2})_{q}(SiR²(OR³)SiO_{2/2})ᵣ(SiO_{4/2})ₛ (1)

wherein R¹ represents a monovalent hydrocarbon group that may be an alkenyl group, R² represents a monovalent hydrocarbon group not containing an alkenyl group, provided that 80% or more of all R² are methyl groups, R³ represents a hydrogen atom or an alkyl group, and m, n, p, q, r, and s are each a number satisfying m≧0, n≧0, p≧0, q≧0, r≧0, s≧0, m+n>0, q+r+s>0, and m+n+p+q+r+s=1;

(c) an organohydrogenpolysiloxane having 2 or more silicon-bonded hydrogen atoms per molecule and having a viscosity at 25° C. of 1,000 mPa·s or less, shown by the following general formula (2), in an amount to provide 0.5 to 5.0 mol of the silicon-bonded hydrogen atoms within the component (c) for every 1 mol of the silicon-bonded alkenyl groups within a combination of the component (a) and the component (b)

R⁴ₐH_{b}SiO_{(4-a-b)/2} (2)

wherein R⁴ represents a monovalent hydrocarbon group except for an alkenyl group, provided that 50% or more of all R⁴ are methyl groups, a and b are each a positive number satisfying 0.7≦a≦2.1, 0.001≦b≦1.0, and 0.8≦a≦3.0; and

(d) a platinum-group metal-based catalyst in an effective amount.

Such component (A) enables a cured product of the silicon adhesive to exhibit higher transparency, low stress, and high hardness.

The component (B) is preferably one or more thermal conductive fillers selected from zinc oxide and alumina.

Such component (B) enables a cured product of the silicone adhesive to have better heat dissipation property.

The component (C) is preferably a hydrocarbon-based solvent.

Such component (C) enables the silicone adhesive to have better workability.

### Advantageous Effects Of Invention

As mentioned above, the inventive silicone adhesive has good workability in the transferring method to a substrate, and is capable of providing a cured product that can effectively dissipate heat generated from a chip and exhibits high adhesiveness, excellent durability, high transparency, low stress, and high hardness.

### DESCRIPTION OF EMBODIMENTS

As mentioned above, it has been desired to develop a silicone adhesive that has good workability in the transferring method to a substrate, and is capable of providing a cured product that can effectively dissipate heat generated from a chip and exhibits high adhesiveness and excellent durability.

The present inventors have intensively studied the above object, and consequently found that the object is accomplished by a silicone adhesive in which a thermal conductive filler with a specific particle size and a solvent with a specific boiling point are added to a silicone resin composition with a specific viscosity, thereby brought the present invention to completion.

That is, the present invention is a silicone adhesive used for bonding a semiconductor device, comprising:

(A) an addition reaction-curable silicone resin composition having a viscosity at 25° C. of 100 Pa·s or less;

(B) a thermal conductive filler having an average particle size of 0.1 μm or more and less than 1 μm; and

(C) a solvent having a boiling point of 250° C. or higher and lower than 350° C., wherein

the component (B) is contained in an amount of 100 to 500 parts by mass based on 100 parts by mass of the component (A), the component (C) is contained in an amount of 5 to 20 parts by mass based on 100 parts by mass of the component (A), and the silicone adhesive uncured has a viscosity at 25° C. of 5 to 100 Pa·s.

Hereinafter, the present invention will be described in detail, but the present invention is not limited thereto.

In the present invention, “type D hardness” means hardness measured with a type D durometer in accordance with JIS K 6253. Also, viscosity is a value measured with a rotational viscometer, a BH-type rotational viscometer (rotor No. 7, 20 rpm), at 25° C. unless stated otherwise. Vi and Me represent a vinyl group and a methyl group, respectively.

### [Component (A)]

The component (A) is an addition reaction-curable silicone resin composition having a viscosity at 25° C. of 100 Pa·s or less.

The viscosity of the component (A) is preferably 1 to 100 Pa·s, more preferably 1 to 10 Pa·s. When the viscosity exceeds 100 Pa·s, the viscosity of the silicone adhesive is so high that workability in the transferring method is deteriorated.

Moreover, a cured product obtained by heating the component (A) at 150° C. for 3 hours exhibits a type D hardness in accordance with JIS K 6253 of preferably 30 degrees or more, more preferably 30 to 90 degrees, much more preferably 40 to 90 degrees.

Such a hardness is preferable since the connectability is stabilized even in a wire bonding step after a LED device is bonded.

The addition reaction-curable silicone resin composition of the component (A) typically contains a main component composed of an organopolysiloxane having silicon-bonded alkenyl groups, a crosslinker composed of an organohydrogenpolysiloxane having silicon-bonded hydrogen atoms (SiH bonds), and a reaction catalyst composed of a platinum-group metal-based catalyst.

Such component (A) preferably comprises:

(a) an organopolysiloxane having 2 or more silicon-bonded alkenyl groups per molecule and having a viscosity at 25° C. of 1,000 mPa·s or less;

(b) an organopolysiloxane having 1 or more silicon-bonded alkenyl groups per molecule in a solid state or a liquid state having a viscosity at 25° C. of 1,000 Pa·s or more, shown by the following average composition formula (1), the component (b) being contained in an amount of 60 to 90 parts by mass based on 100 parts by mass of a total of the component (a) and the component (b),

(R¹R²₂SiO_{1/2})ₘ(R¹R²SiO_{2/2})ₙ(R²₂SiO_{2/2})ₚ(R¹SiO_{3/2})_{q}(SiR²(OR³)SiO_{2/2})ᵣ(SiO_{4/2})ₛ (1)

wherein R¹ represents a monovalent hydrocarbon group that may be an alkenyl group, R² represents a monovalent hydrocarbon group not containing an alkenyl group, provided that 80% or more of all R² are methyl groups, R³ represents a hydrogen atom or an alkyl group, and m, n, p, q, r, and s are each a number satisfying m≧0, n≧0, p≧0, q≧0, r≧0, s≧0, m+n>0, q+r+s>0, and m+n+p+q+r+s=1;

(c) an organohydrogenpolysiloxane having 2 or more silicon-bonded hydrogen atoms per molecule and having a viscosity at 25° C. of 1,000 mPa·s or less, shown by the following general formula (2), in an amount to provide 0.5 to 5.0 mol of the silicon-bonded hydrogen atoms within the component (c) for every 1 mol of the silicon-bonded alkenyl groups within a combination of the component (a) and the component (b)

R⁴ₐH_{b}SiO_{(4-a-b)/2} (2)

wherein R⁴ represents a monovalent hydrocarbon group except for an alkenyl group, provided that 50% or more of all R⁴ are methyl groups, a and b are each a positive number satisfying 0.7≦a≦2.1, 0.001≦b≦1.0, and 0.8≦a+b≦3.0; and

(d) a platinum-group metal-based catalyst in an effective amount.

### Component (a)

The component (a) is a component for imparting stress relaxation to the silicone resin composition of the component (A) after curing. The component (a) is an organopolysiloxane having 2 or more silicon-bonded alkenyl groups per molecule and having a viscosity at 25° C. of 1,000 mPa·s or less. Typically, the component (a) is a linear organopolysiloxane in which the main chain is composed of repeating diorganosiloxane units and both the molecular chain terminals are blocked with triorganosiloxy groups.

Illustrative examples of the component (a) include organopolysiloxanes shown by the following:
ViR₂SiO(SiR₂O)_{y}SiR₂Vi,
ViR₂SiO(SiRViO)ₓ(SiR₂O)_{y}SiR₂Vi,
Vi₂RSiO(SiR₂O)_{y}SiRVi₂,
Vi₃SiO(SiR₂O)_{y}SiVi₃,
Vi₂RSiO(SiRViO)ₓ(SiR₂O)_{y}SiRVi₂,
Vi₃SiO(SiRViO)ₓ(SiR₂O)_{y}SiVi₃, and
R₃SiO(SiRViO)ₓ(SiR₂O)_{y}SiR₃
   wherein R represents a monovalent hydrocarbon group containing neither an aliphatic unsaturated group nor an aryl group, and preferably having 10 or less carbon atoms; x represents an integer of 0 to 5; and y represents an integer of 0 to 200. In view of light resistance and heat resistance, R is preferably a methyl group.

More specifically, examples of the component (a) include
ViMe₂SiO(Me₂SiO)₂₀SiMe₂Vi,
ViMe₂SiO(Me₂SiO)₉₀SiMe₂Vi,
ViMe₂SiO(MeViSiO)₁(Me₂SiO)₁₉SiMe₂Vi, and
Me₃SiO(MeViSiO)₂(Me₂SiO)₁₈SiMe₃.

The viscosity at 25° C. of the component (a) is 1,000 mPa·s or less, preferably 700 mPa·s or less (typically 10 to 700 mPa·s), much more preferably 20 to 200 mPa·s. When the viscosity is 1,000 mPa·s or less, a cured product obtained by curing the inventive silicone adhesive exhibits a sufficient crosslinking density to achieve high hardness.

The component (a) used may be one kind or a combination of two or more kinds.

### Component (b)

The component (b) is a component for providing reinforcement while retaining the transparency of the silicone resin composition of the component (A). Specifically, the component (b) is an organopolysiloxane having 1 or more silicon-bonded alkenyl groups per molecule in a solid state or a liquid state having a viscosity at 25° C. of 1,000 Pa·s or more, as shown by the following average composition formula (1),

R¹R²₂SiO_{2/2})ₘ(R¹R²SiO_{2/2})ₙ(R²₂SiO_{2/2})ₚ(R¹SiO_{3/2})_{q}(SiR²(OR³)SiO_{2/2})ᵣ(SiO_{4/2})ₛ (1)

wherein R¹ represents a monovalent hydrocarbon group that may be an alkenyl group, R² represents a monovalent hydrocarbon group not containing an alkenyl group, provided that 80% or more of all R² are methyl groups, R³ represents a hydrogen atom or an alkyl group, and m, n, p, q, r, and s are each a number satisfying m≧0, n≧0, p≧0, q≧0, r≧0, s≧0, m+n>0, q+r+s>0, and m+n+p+q+r+s=1.

In the average composition formula (1), R¹ represents a monovalent hydrocarbon group that may be an alkenyl group. When R¹ represents an alkenyl group, the alkenyl group is preferably a vinyl group in view of ease of availability and cost. The amount of the alkenyl groups is preferably within the range of 0.01 to 1 mol/100 g, more preferably 0.05 to 0.5 mol/100 g with respect to a solid of the component (b).

When the amount of the alkenyl groups is 0.01 mol/100 g or more, this component is sufficiently incorporated in crosslinking, consequently enabling a silicone adhesive that is capable of providing a cured product with high hardness to be obtained. When the amount of the alkenyl groups is 1 mol/100 g or less, the alkenyl groups in the system is not excessively increased. Therefore, even if the formulation amount of a later-described crosslinker (component (c)) is small, the crosslinking reaction proceeds adequately, enabling a cured product with a desired hardness to be obtained. In addition, even if the amount of the crosslinker is increased, since the concentration of the component (b) is not excessively low, the cured product to be obtained can be prevented from becoming fragile.

When R¹ is not an alkenyl group, examples of R¹ include substituted or unsubstituted monovalent hydrocarbon groups having typically 1 to 12 carbon atoms, preferably 1 to 10 carbon atoms. Examples of the substituted or unsubstituted monovalent hydrocarbon group include alkyl groups such as a methyl group, an ethyl group, a propyl group, a butyl group, a pentyl group, a hexyl group, and a heptyl group; cycloalkyl groups such as a cyclohexyl group; aryl groups such as a phenyl group, a tolyl group, a xylyl group, and a naphthyl group; aralkyl groups such as a benzyl group and a phenethyl group; and groups in which a part or all of hydrogen atoms in these groups are substituted with halogen atoms such as chlorine, fluorine, and bromine, including halogenated alkyl groups such as a chloromethyl group, a 3-chloropropyl group, and a 3,3,3-trifluoropropyl group. Among them, alkyl groups are preferable, and a methyl group is more preferable.

In the average composition formula (1), R² represents a monovalent hydrocarbon group not containing an alkenyl group. R² may be a group mentioned above as examples of R¹ except for an alkenyl group, preferably an alkyl group, more preferably a methyl group.

80% or more of all R² are methyl groups. The proportion of methyl groups is preferably 90% to 100%, more preferably 98% to 100%. When the proportion of methyl groups is 80% or more of all R², good compatibility with the component (a) is achieved, thus enabling a highly transparent cured product to be obtained.

In the average composition formula (1), R³ represents a hydrogen atom or an alkyl group, preferably a hydrogen atom or a methyl group.

In the average composition formula (1), m, n, p, q, r, and s are each a number satisfying m≧0, n≧0, p≧0, q≧0, r≧0, s≧0, m+n>0, q+r+s>0, and m+n+p+q+r+s=1. m is preferably from 0 to 0.65, n is preferably from 0 to 0.5, p is preferably from 0 to 0.5, q is preferably from 0 to 0.8, r is preferably from 0 to 0.8, and s is preferably from 0 to 0.6. Furthermore, m+n is preferably from 0.1 to 0.8, and q+r+s is preferably from 0.1 to 0.8.

The viscosity at 25° C. of the component (b) is 1,000 Pa·s or more, preferably 10,000 Pa·s or more. Otherwise, the component (b) is solid. The viscosity of 1,000 Pa·s or more prevents the viscosity of the component (A) from excessively decreasing, therefore it is preferable.

The ratio of the component (b) to the component (a) is also important to the component (A). The component (b) is contained in amount of preferably 60 to 90 parts by mass, more preferably 70 to 80 parts by mass, based on 100 parts by mass of the total of the component (a) and the component (b). When the component (b) is 60 parts by mass or more, a desired hardness can be obtained. When the amount is 90 parts by mass or less, a cured product of the silicone resin composition can be prevented from becoming excessively fragile. Consequently, the inventive silicone adhesive is more suitably used for a die bonding material for a LED device.

The component (b) used may be one kind or a combination of two or more kinds.

### Component (c)

The component (c) is a component used as a crosslinker for proceeding crosslinking with the alkenyl groups contained in the component (a) and the component (b) by the hydrosilylation reaction. Specifically, the component (c) is an organohydrogenpolysiloxane having 2 or more silicon-bonded hydrogen atoms (SiH groups) per molecule and having a viscosity at 25° C. of 1,000 mPa·s or less, shown by the following general formula (2)

R⁴ₐH_{b}SiO_{(4-a-b)/2} (2)

wherein R⁴ represents a monovalent hydrocarbon group except for an alkenyl group, provided that 50% or more of all R⁴ are methyl groups, a and b are each a positive number satisfying 0.7≦a≦2.1, 0.001≦b≦1.0, and 0.8≦a+b≦3.0.

In the general formula (2), R⁴ represents a monovalent hydrocarbon group having preferably 1 to 10 carbon atoms, particularly preferably 1 to 8 carbon atoms, except for an alkenyl group. Examples thereof include alkyl groups such as a methyl group, an ethyl group, a propyl group, an isopropyl group, a butyl group, an isobutyl group, a tert-butyl group, a pentyl group, a neopentyl group, a hexyl group, a cyclohexyl group, an octyl group, a nonyl group, and a decyl group; aryl groups such as a phenyl group, a tolyl group, a xylyl group, and a naphthyl group; aralkyl groups such as a benzyl group, a phenylethyl group, and a phenylpropyl group. Among them, a methyl group or a phenyl group is particularly preferable.

In the general formula (2), a and b are each a positive number satisfying 0.7≦a≦2.1, 0.001≦b≦1.0, and 0.8≦a+b≦3.0. a is preferably from 1.0 to 2.0, b is preferably from 0.01 to 1.0. Furthermore, a+b is preferably from 1.1 to 2.6.

The component (c) contains 2 or more (typically 2 to 200), preferably 3 or more (for example, 3 to 100), more preferably about 4 to 50 SiH groups per molecule. These SiH groups may be positioned at the molecular chain terminals or within the molecular chain, or may be positioned at both the locations. Although the molecular structure of this organohydrogenpolysiloxane may be any of a linear, cyclic, branched, or three dimensional network structure, the number of silicon atoms per molecule (or the polymerization degree) is typically within the range of 2 to 200, preferably 3 to 100, more preferably 4 to 50, approximately.

Examples of the component (c) include 1,1,3,3-tetramethyldisiloxane, 1,3,5,7-tetramethylcyclotetra-siloxane, tris(hydrogendimethylsiloxy)methylsilane, tris(hydrogendimethylsiloxy)phenylsilane, methylhydrogen-cyclopolysiloxane, cyclic copolymers of methylhydrogen-siloxane and dimethylsiloxane, methylhydrogenpolysiloxane with both terminals blocked with trimethylsiloxy groups, copolymers of dimethylsiloxane and methylhydrogensiloxane with both terminals blocked with trimethylsiloxy groups, dimethylpolysiloxane with both terminals blocked with dimethylhydrogensiloxy groups, methylhydrogenpolysiloxane with both terminals blocked with dimethylhydrogensiloxy groups, copolymers of dimethylsiloxane and methylhydrogen-siloxane with both terminals blocked with dimethyl-hydrogensiloxy groups, copolymers of methylhydrogen-siloxane and diphenylsiloxane with both terminals blocked with trimethylsiloxy groups, copolymers of methyl-hydrogensiloxane, diphenylsiloxane, and dimethylsiloxane with both terminals blocked with trimethylsiloxy groups, copolymers of methylhydrogensiloxane, methylphenylsiloxane, and dimethylsiloxane with both terminals blocked with trimethylsiloxy groups, copolymers of methylhydrogen-siloxane, dimethylsiloxane, and diphenylsiloxane with both terminals blocked with dimethylhydrogensiloxy groups, copolymers of methylhydrogensiloxane, dimethylsiloxane, and methylphenylsiloxane with both terminals blocked with dimethylhydrogensiloxy groups, copolymers composed of (CH₃)₂HSiO_{1/2} units, (CH₃)₃SiO_{1/2} units, and SiO_{4/2} units, copolymers composed of (CH₃)₂HSiO_{1/2} units and SiO_{4/2} units, copolymers composed of (CH₃)₂HSiO_{1/2} units, SiO_{4/2} units, and (C₆H₅)₃SiO_{1/2} units, and compounds in which a part or all of methyl groups in the above exemplary compounds are substituted with phenyl groups.

More specifically, illustrative examples of the component (c) include Me₃SiO(MeHSiO)_{z}SiMe₃ (wherein z represents an integer of 2 to 100, preferably 2 to 20) and cyclic siloxanes shown by the following formula.

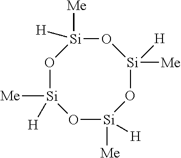 [SMILES: C[SiH]1O[SiH](C)O[SiH](C)O[SiH](C)O1]

The viscosity at 25° C. of the component (c) is 1,000 mPa·s or less, preferably 0.5 to 1,000 mPa·s, more preferably 2 to 200 mPa·s. When the viscosity is 1,000 mPa·s or less, a cured product obtained by curing the inventive silicone adhesive achieves a sufficient crosslinking density, enabling the cured product to have high hardness.

The formulation amount of the component (c) is, in view of crosslinking balance, an amount to provide 0.5 to 5.0 mol, preferably 0.7 to 3.0 mol of the silicon-bonded hydrogen atoms (SiH groups) within the component (c) for every 1 mol of the silicon-bonded alkenyl groups within a combination of the component (a) and the component (b). When the formulation amount is within the above range, the crosslinking sufficiently proceeds to provide a cured product with high hardness.

The component (c) used may be one kind or a combination of two or more kinds.

### Component (d)

The component (d) is a platinum-group metal-based catalyst in an effective amount, which serves as a reaction catalyst for promoting hydrosilylation reaction of the components (a) and (b) with the component (c).

As the platinum-group metal-based catalyst, any known catalysts for hydrosilylation reaction can be used. Examples thereof include simple substances of platinum group metal such as platinum black, rhodium, and palladium; platinum chloride, chloroplatinic acid, and chloroplatinic acid salts such as H₂PtCl₄.kH₂O, H₂PtCl₆.kH₂O, NaHPtCl₆.kH₂O, KHPtCl₆.kH₂O, Na₂PtCl₆.kH₂O, K₂PtCl₄.kH₂O, PtCl₄.kH₂O, PtCl₂, Na₂HPtCl₄.kH₂O (wherein k is an integer of 0 to 6, preferably 0 or 6); alcohol-modified chloroplatinic acid (see U.S. Pat. No. 3,220,972); complexes of chloroplatinic acid with olefins (see U.S. Pat. No. 3,159,601, U.S. Pat. No. 3,159,662, and U.S. Pat. No. 3,775,452); platinum group metals such as platinum black and palladium on supports such as alumina, silica, and carbon; rhodium-olefin complexes; chlorotris(triphenylphosphine)rhodium (Wilkinson's catalyst); and complexes of platinum chloride, chloroplatinic acid, or chloroplatinic acid salts with vinyl group-containing siloxane, particularly, vinyl group-containing cyclic siloxane. Among them, in view of compatibility and chloride impurities, silicone-modified chloroplatinic acid is preferable. Illustrative examples thereof include platinum catalysts in which chloroplatinic acid is modified with tetramethylvinyldisiloxane. The adding amount thereof is 1 to 500 ppm, preferably 3 to 100 ppm, more preferably 5 to 40 ppm, in terms of the weight of platinum atoms in the component (A).

The component (d) used may be one kind or a combination of two or more kinds.

The addition reaction-curable silicone resin composition of the component (A) used in the inventive silicone adhesive can be obtained by mixing the above-described components (a), (b), (c), and (d).

### [Component (B)]

The component (B) is a thermal conductive filler having an average particle size of 0.1 μm or more and less than 1 which serves as a filler for imparting thermal conductivity (heat dissipation property) to the silicone adhesive to be obtained.

Examples of the thermal conductive filler include zinc oxide, alumina, boron nitride, and aluminum nitride. In view of thermal conductivity, moisture resistance, and average particle size, zinc oxide and alumina are preferable.

The component (B) used may be one kind or a combination of two or more kinds.

Specific average particle size is required to efficiently dissipate heat from a light-emitting device. The average particle size of the thermal conductive filler must be, in view of heat dissipation property, 0.1 μm or more and less than 1 or is preferably 0.1 to 0.9 μm, more preferably 0.3 to 0.9 μm. When the average particle size is 1 μm or more, the adhesive thickness is thickened, which causes deterioration of heat dissipation property for heat generated from a light-emitting device to be bonded. When the average particle size is less than 0.1 μm, the viscosity of the composition is increased, and transferring property is deteriorated.

The formulation amount of the component (B) is 100 to 500 parts by mass, preferably 150 to 350 parts by mass, based on 100 parts by mass of the component (A). When the formulation amount of the component (B) exceeds 500 parts by mass, the silicone adhesive to be obtained exhibits so high viscosity that stringiness occurs, which causes difficulty in application of the adhesive by transferring method (stamping method). When the formulation amount of the component (B) is less than 100 parts by mass, sufficient heat dissipation property cannot be obtained.

### [Component (C)]

The component (C) is a solvent having a boiling point of 250° C. or higher and lower than 350° C., which serves as a dilution solvent for imparting flowability to the composition containing the component (A) and the component (B).

When the component (B) is added for the purpose of imparting sufficient thermal conductivity to the component (A), the composition containing the component (A) and the component (B) becomes semi-solid and has no flowability, thus the composition is difficult to be applied to the transferring method. The combination with the component (C) enables the composition to have flowability and to be applied to the transferring method.

The component (C) is not particularly limited so long as it is a solvent having a boiling point of 250° C. or higher and lower than 350° C. and capable of dissolving the component (A). A hydrocarbon-based solvent excellent in solubility is preferable.

In the transferring method, an adhesive is applied on a perforated plate to form a thin film, and the thin film is transferred by stamping to a substrate on which a LED light-emitting device will be mounted. In this context, the adhesive requires stable viscosity during the transferring step. Use of the solvent having a boiling point of lower than 250° C. causes problems that constant amount of the adhesive cannot be transferred or that voids are generated in the cured product, because the viscosity increases in use. Use of the solvent having a boiling point of 350° C. or higher may adversely affect reliability of LED because the solvent remains in the cured product.

The formulation amount of the component (C) is 5 to 20 parts by mass, preferably 5 to 15 parts by mass, based on 100 parts by mass of the component (A). When the formulation amount is less than 5 parts by mass, the adhesive exhibits high viscosity, which causes a problem of stringiness in the transferring step. When the formulation amount exceeds 20 parts by mass, the transferring amount is reduced, resulting in deterioration of adhesiveness in some cases.

### [Other Additives]

If necessary, the inventive silicone adhesive may further contain materials as shown below: silicone non-functional oil as a viscosity control agent; carbon functional silane and silicone compounds modified with an epoxy group, SiH group, SiVi group, or alkoxy group (the compound may be modified with one group or multiple groups) for the purpose of improving adhesiveness; components for controlling curing speed such as acetylene alcohol compounds typified by tetramethyltetravinyl-cyclosiloxane and ethynylcyclohexanol, triallyl-isocyanurate and modified compound thereof; and hindered amine, antioxidant, and polymerization inhibitor for enhancing heat resistance.

The inventive silicone adhesive can be obtained by mixing the above-described components (A), (B), (C) and, if necessary, other additives.

In order to achieve good workability in the transferring method, the viscosity at 25° C. of the inventive silicone adhesive should be 5 to 100 Pa·s, or is preferably 20 to 50 Pa·s.

Moreover, the curing condition of the inventive silicone adhesive is preferably, but not limited to, at 120 to 180° C. for 60 to 180 minutes.

As examples of a semiconductor device to which the inventive silicone adhesive is applied, there may be mentioned a light-emitting diode (LED) chip.

As mentioned above, the inventive silicone adhesive has good workability in the transferring method to a substrate, and is capable of providing a cured product that can effectively dissipate heat generated from a chip and exhibits high adhesiveness, excellent durability, high transparency, low stress, and high hardness.

### EXAMPLE

Hereinafter, the present invention will be more specifically described with reference to synthesis example, examples, and comparative examples, but the present invention is not limited thereto.

### Synthesis Example

(1) A linear dimethylpolysiloxane (a1) with both terminals blocked with vinyl groups, having a viscosity at 25° C. of 70 mPa·s, a toluene solution of a silicone resin (b1) composed of Me₃SiO_{1/2} units, ViMe₂SiO_{1/2} units, and SiO_{4/2} units in which the mole ratio of Me₃SiO_{1/2} and ViMe₂SiO_{1/2} to SiO_{4/2} is 0.8 and the amount of vinyl groups per solid is 0.085 mol/100 g, and a methylhydrogensiloxane (c1) with both terminals blocked with trimethylsiloxy groups, having a viscosity at 25° C. of 7.5 mPa·s, as represented by the general formula (2): R⁴ₐH_{b}SiO_{(4-a-b)/2} wherein R⁴ is a methyl group, a=1.44, and b=0.78 were mixed with a mass ratio of (a1):(b1):(c1)=25:75:10 in terms of effective components. The toluene was removed from the resulting mixture under reduced pressure of 10 mmHg or less at 120° C., thereby obtaining a liquid that was viscous at room temperature.
(2) To 100 parts by mass of the liquid were added 3 parts by mass of tetramethyltetravinyltetracyclosiloxane and 5 parts by mass of an epoxy group-containing siloxane compound shown by the following structural formula and mixed to obtain a transparent liquid having a viscosity of 5 Pa·s (Silicone base 1 with a mole ratio of the total SiH groups to the total alkenyl groups in the composition of 1.65).

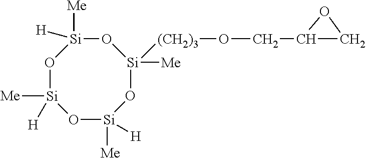

(3) Furthermore, to 100 parts by mass of Silicone base 1 was added a platinum catalyst (d1) having tetramethyl-vinyldisiloxane ligands, derived from chloroplatinic acid, in an amount of 10 ppm in terms of platinum atoms with respect to the silicone components, these components were uniformly mixed, and the obtained composition was heated at 150° C. for 3 hours. The type D hardness of the obtained composition was 50.

### Example 1

To 100 parts by mass of Silicone base 1 obtained in the same manner as in Synthesis example were added 230 parts by mass of a pulverized zinc oxide (B1) having an average particle size of 0.3 μm (two types of zinc oxide, available from Mitsui Kinzoku Kogyo Co., Ltd.) and a platinum catalyst (d1) having tetramethylvinyldisiloxane ligands, derived from chloroplatinic acid, in an amount of 10 ppm in terms of platinum atoms with respect to the silicone components, and these components were uniformly mixed. Then, 13.3 parts by mass of a hydrocarbon-based solvent (C1) having a boiling point of 275 to 330° C. (HYDROSEAL G3H, available from TOTAL S.A.) was added thereto, and the solution was uniformly mixed to obtain a white paste having a viscosity of 28 Pa·s.

### Example 2

To 100 parts by mass of Silicone base 1 obtained in the same manner as in Synthesis example were added 230 parts by mass of the same pulverized zinc oxide (B1) as used in Example 1 and the same platinum catalyst (d1) as used in Example 1 in an amount of 10 ppm in terms of platinum atoms with respect to the silicone components, and these components were uniformly mixed. Then, 7.9 parts by mass of the same hydrocarbon-based solvent (C1) as used in Example 1 was added thereto, and the solution was uniformly mixed to obtain a white paste having a viscosity of 42 Pa·s.

### Example 3

To 100 parts by mass of Silicone base 1 obtained in the same manner as in Synthesis example were added 200 parts by mass of spherical alumina (B2) having an average particle size of 0.7 μm (AO-802, available from Admatechs Co., Ltd.) and the same platinum catalyst (d1) as used in Example 1 in an amount of 10 ppm in terms of platinum atoms with respect to the silicone components, and these components were uniformly mixed. Then, 11.5 parts by mass of a hydrocarbon-based solvent (C2) having a boiling point of 250 to 330° C. (HYDROSEAL G250H, available from TOTAL S.A.) was added thereto, and the solution was uniformly mixed to obtain a white paste having a viscosity of 29.5 Pa·s.

### Example 4

To 100 parts by mass of Silicone base 1 obtained in the same manner as in Synthesis example were added 330 parts by mass of spherical alumina (B3) having an average particle size of 0.9 μm (AL-47-1, available from SHOWA DENKO K.K.) and the same platinum catalyst (d1) as used in Example 1 in an amount of 10 ppm in terms of platinum atoms with respect to the silicone components, and these components were uniformly mixed. Then, 11.5 parts by mass of the same hydrocarbon-based solvent (C2) as used in Example 3 was added thereto, and the solution was uniformly mixed to obtain a white paste having a viscosity of 50 Pa·s.

### Comparative Example 1

A milky white semi-transparent paste having a viscosity of 50 Pa·s was obtained in the same manner as in Example 1 except that 4.6 parts by mass of fumed silica having a primary particle size of 7 nm (REOLOSIL DM-30, available from K.K. Tokuyama) was used instead of the zinc oxide (B1) of the component (B) and the hydrocarbon-based solvent (C1) of the component (C) was not added.

### Comparative Example 2

A semi-solid composition having no flowability was obtained in the same manner as in Example 1 except that the hydrocarbon-based solvent (C1) of the component (C) was not added.

### Comparative Example 3

A white paste having a viscosity of 29.0 Pa·s was obtained in the same manner as in Example 3 except that n-hexane having a boiling point of 69° C. was used instead of the hydrocarbon-based solvent (C2) of the component (C).

### Comparative Example 4

A white paste having a viscosity of 32.0 Pa·s was obtained in the same manner as in Example 3 except that a hydrocarbon solvent having a boiling point of 350° C. or higher (GEMSEAL120, available from TOTAL S.A.) was used instead of the hydrocarbon-based solvent (C2) of the component (C).

The white pastes thus prepared were subjected to the following tests. The result of the test is given in Table 1.

### [Hardness of Cured Product]

The pastes obtained in examples and comparative examples were heated at 150° C. for 3 hours. The type D hardness of the obtained cured products was measured in accordance with JIS K 6253.

### [Thermal Conductivity]

The thermal conductivity was measured by Hot-wire method with a quick thermal conductivity meter (QTM-500, available from Kyoto electronics manufacturing Co., Ltd.).

### [Transferring Property]

The pastes were transferred with a fixed amount to a silver-plated electrode portion of SMD5050 package (resin PPA, available from I-CHIUN PRECISION INDUSTRY Co.) by stamping with a die bonder (AD-830, available from ASM Ltd.), and workability when an optical semiconductor device (EV-B35A, 35 mil, available from SemiLED Corp.) was mounted thereon was evaluated.

### [Adhesiveness]

The package produced in the test for evaluating the transferring property was put into an oven at 150° C. and heated for 3 hours to cure the adhesive. The die shear strength was then measured with a bond tester (Series4000, available from Dage Co., Ltd.).

### [Adhesiveness After High Temperature Energization]

A current of 350 mA was applied to the package obtained in the adhesiveness evaluation for 1,000 hours at high temperature (85° C.), and the die shear strength was then measured.

TABLE 1

| | | | | | Comparative | Comparative | Comparative | Comparative |
|---|---|---|---|---|---|---|---|---|
| | Example 1 | Example 2 | Example 3 | Example 4 | example 1 | example 2 | example 3 | example 4 |
| Hardness | 70 | 74 | 78 | 78 | 56 | molding | 78 | 15 |
| (Type D) | | | | | | defect | | |
| | | | | | | un- | | |
| | | | | | | measurable | | |
| Thermal | 0.6 | 0.6 | 0.6 | 1.0 | 0.2 | molding | 0.6 | 0.5 |
| conductivity | | | | | | defect | | |
| (W/m · k) | | | | | | un- | | |
| | | | | | | measurable | | |
| Transferring | good | good | good | good | good | cannot be | Defect | good |
| property | | | | | | transferred | (stringiness | |
| | | | | | | due to non- | due to | |
| | | | | | | flowability | thickening | |
| | | | | | | | over time) | |
| Adhesiveness | 14.4 | 15.2 | 15.0 | 14.8 | 15.5 | un- | un- | 2.0 |
| (MPa) | | | | | | measurable | measurable | |
| Adhesiveness | 14.2 | 15.2 | 14.9 | 15.0 | 16.0 | un- | un- | 4.0 |
| after high | | | | | | measurable | measurable | |
| temperature | | | | | | | | |
| energization | | | | | | | | |
| (MPa) | | | | | | | | |

As shown in Table 1, in Examples 1 to 4, which contained, in addition to the addition reaction-curable silicone resin composition of the component (A), the thermal conductive filler of the component (B) and the solvent of the component (C), the adhesive exhibited good transferring property (workability) and cured into a cured product excellent in adhesiveness, hardness, and thermal conductivity (heat dissipation property).

On the other hand, in Comparative example 1, which contained neither the component (B) nor the component (C), the cured product did not exhibit sufficient heat dissipation property and was inferior in hardness to Examples 1 to 4. In Comparative example 2, which contained the component (B) but not the component (C), the mixture was in a semi-solid state without flowability, and thus could not be used in the transferring method. In Comparative example 3, which used the solvent having low boiling point instead of the component (C), the viscosity increased in the transferring step, and stringiness occurred. Therefore, transferring could not be done. Furthermore, in Comparative example 4, which used the solvent having high boiling point instead of the component (C), the hardness was inadequate and the adhesiveness was low.

As described above, the inventive silicone adhesive has good workability in the transferring method to a substrate, and is capable of providing a cured product that can effectively dissipate heat generated from a chip and exhibits high adhesiveness and excellent durability.

It is to be noted that the present invention is not limited to the foregoing embodiment. The embodiment is just an exemplification, and any examples that have substantially the same feature and demonstrate the same functions and effects as those in the technical concept described in claims of the present invention are included in the technical scope of the present invention.

1-5. (canceled)

6. A silicone adhesive used for bonding a semiconductor device, comprising:
(A) an addition reaction-curable silicone resin composition having a viscosity at 25° C. of 100 Pa·s or less;
(B) a thermal conductive filler having an average particle size of 0.1 μm or more and less than 1 μm; and
(C) a solvent having a boiling point of 250° C. or higher and lower than 350° C., wherein
the component (B) is contained in an amount of 100 to 500 parts by mass based on 100 parts by mass of the component (A), the component (C) is contained in an amount of 5 to 20 parts by mass based on 100 parts by mass of the component (A), and the silicone adhesive uncured has a viscosity at 25° C. of 5 to 100 Pa·s.

7. The silicone adhesive according to claim 6, wherein a cured product obtained by heating the component (A) at 150° C. for 3 hours exhibits a type D hardness in accordance with JIS K 6253 of 30 degrees or more.

8. The silicone adhesive according to claim 6, wherein the component (A) comprises:
(a) an organopolysiloxane having 2 or more silicon-bonded alkenyl groups per molecule and having a viscosity at 25° C. of 1,000 mPa·s or less;
(b) an organopolysiloxane having 1 or more silicon-bonded alkenyl groups per molecule in a solid state or a liquid state having a viscosity at 25° C. of 1,000 Pa·s or more, shown by the following average composition formula (1), the component (b) being contained in an amount of 60 to 90 parts by mass based on 100 parts by mass of a total of the component (a) and the component (b),
(R¹R²₂SiO_{1/2})ₘ(R¹R²SiO_{2/2})ₙ(R²₂SiO_{2/2})ₚ(R¹SiO_{3/2})_{q}(SiR²(OR³)SiO_{2/2})ᵣ(SiO_{4/2})ₛ (1)
wherein R¹ represents a monovalent hydrocarbon group that may be an alkenyl group, R² represents a monovalent hydrocarbon group not containing an alkenyl group, provided that 80% or more of all R² are methyl groups, R³ represents a hydrogen atom or an alkyl group, and m, n, p, q, r, and s are each a number satisfying m≧0, n≧0, p≧0, r≧0, q≧0, r≧0, s≧0, m+n>0, q+r+s>0, and m+n+p+q+r+s=1;
(c) an organohydrogenpolysiloxane having 2 or more silicon-bonded hydrogen atoms per molecule and having a viscosity at 25° C. of 1,000 mPa·s or less, shown by the following general formula (2), in an amount to provide 0.5 to 5.0 mol of the silicon-bonded hydrogen atoms within the component (c) for every 1 mol of the silicon-bonded alkenyl groups within a combination of the component (a) and the component (b)
R⁴ₐH_{b}SiO_{(4-a-b)/2} (2)
wherein R⁴ represents a monovalent hydrocarbon group except for an alkenyl group, provided that 50% or more of all R⁴ are methyl groups, a and b are each a positive number satisfying 0.7≦a≦2.1, 0.001≦b≦1.0, and 0.8≦a+b≦3.0; and
(d) a platinum-group metal-based catalyst in an effective amount.

9. The silicone adhesive according to claim 7, wherein the component (A) comprises:
(a) an organopolysiloxane having 2 or more silicon-bonded alkenyl groups per molecule and having a viscosity at 25° C. of 1,000 mPa·s or less;
(b) an organopolysiloxane having 1 or more silicon-bonded alkenyl groups per molecule in a solid state or a liquid state having a viscosity at 25° C. of 1,000 Pa·s or more, shown by the following average composition formula (1), the component (b) being contained in an amount of 60 to 90 parts by mass based on 100 parts by mass of a total of the component (a) and the component (b),
(R¹R²₂SiO_{1/2})ₘ(R¹R²SiO_{2/2})ₙ(R²₂SiO_{2/2})ₚ(R¹SiO_{3/2})_{q}(SiR²(OR³)SiO_{2/2})ᵣ(SiO_{4/2})ₛ (1)
wherein R¹ represents a monovalent hydrocarbon group that may be an alkenyl group, R² represents a monovalent hydrocarbon group not containing an alkenyl group, provided that 80% or more of all R² are methyl groups, R³ represents a hydrogen atom or an alkyl group, and m, n, p, q, r, and s are each a number satisfying m≧0, n≧0, p≧0, q≧0, r≧0, s≧0, m+n>0, q+r+s>0, and m+n+p+q+r+s=1;
(c) an organohydrogenpolysiloxane having 2 or more silicon-bonded hydrogen atoms per molecule and having a viscosity at 25° C. of 1,000 mPa·s or less, shown by the following general formula (2), in an amount to provide 0.5 to 5.0 mol of the silicon-bonded hydrogen atoms within the component (c) for every 1 mol of the silicon-bonded alkenyl groups within a combination of the component (a) and the component (b)
R⁴ₐH_{b}SiO_{(4-a-b)/2} (2)
wherein R⁴ represents a monovalent hydrocarbon group except for an alkenyl group, provided that 50% or more of all R⁴ are methyl groups, a and b are each a positive number satisfying 0.7≦a≦2.1, 0.001≦b≦1.0, and 0.8≦a+b≦3.0; and
(d) a platinum-group metal-based catalyst in an effective amount.

10. The silicone adhesive according to claim 6, wherein the component (B) is one or more thermal conductive fillers selected from zinc oxide and alumina.

11. The silicone adhesive according to claim 7, wherein the component (B) is one or more thermal conductive fillers selected from zinc oxide and alumina.

12. The silicone adhesive according to claim 8, wherein the component (B) is one or more thermal conductive fillers selected from zinc oxide and alumina.

13. The silicone adhesive according to claim 9, wherein the component (B) is one or more thermal conductive fillers selected from zinc oxide and alumina.

14. The silicone adhesive according to claim 6, wherein the component (C) is a hydrocarbon-based solvent.

15. The silicone adhesive according to claim 7, wherein the component (C) is a hydrocarbon-based solvent.

16. The silicone adhesive according to claim 8, wherein the component (C) is a hydrocarbon-based solvent.

17. The silicone adhesive according to claim 9, wherein the component (C) is a hydrocarbon-based solvent.

18. The silicone adhesive according to claim 10, wherein the component (C) is a hydrocarbon-based solvent.

19. The silicone adhesive according to claim 11, wherein the component (C) is a hydrocarbon-based solvent.

20. The silicone adhesive according to claim 12, wherein the component (C) is a hydrocarbon-based solvent.

21. The silicone adhesive according to claim 13, wherein the component (C) is a hydrocarbon-based solvent.
